(19) United States
(12) Patent Application Publication
(10) Pub. No.: US 2004/0004217 A1
(43) Pub. Date: Jan. 8, 2004

(54) Semiconductor opto-electronic devices with wafer bonded gratings

(76) Inventor: Vijaysekhar Jayaraman, Goleta, CA (US)

Correspondence Address: VIJAYSEKHAR JAYARAMAN, 270 CORONADO DRIVE, GOLETA, CA, 93117, US

(21) Appl. No.: 10/382,166

(22) Filed: Mar. 5, 2003

Related U.S. Application Data
(60) Provisional application No. 60/362,300, filed on Mar. 6, 2002.

(51) Int. Cl. H01L 29/04; H01L 31/036; H01L 31/0376; H01L 31/20

(52) U.S. Cl. 257/53

(57) ABSTRACT

A semiconductor opto-electronic device according to the present invention has a grating disposed at an electrically passive wafer bonded interface. The device has p and n contacts, and current path between the contacts that does not traverse the wafer bonded interface. The absence of current injection across defective interfaces leads to a device with improved reliability relative to prior art regrowth approaches. The present invention can be combined with vertical and lateral wafer bonding to create grating-based devices with an active/passive transition, such as tunable lasers.

### BACKGROUND—CROSS-REFERENCES TO RELATED APPLICATIONS

This application is entitled to the benefit of Provisional Patent Application Serial No. 60/362300, filed Mar. 6, 2002. Additionally, the specification references my co-pending U.S Patent Application entitled “Multiple Epitaxial Region Wafers with Optical Connectivity,” filed by Vijaysekhar Jayaraman Jan. 15, 2003.

### BACKGROUND—FIELD OF THE INVENTION

This invention relates generally to single-mode lasers, distributed bragg reflector lasers, distributed feedback lasers, tunable lasers, tunable filters and wafer bonding.

### BACKGROUND—DESCRIPTION OF PRIOR ART

Semiconductor opto-electronic devices employing gratings include distributed bragg reflector (DBR) lasers, distributed feedback (DFB) lasers, sampled grating DBR (SGDBR) lasers, and grating assisted co-directional coupler lasers (GACC). Each of these laser structures can also function as a filter with slight modifications. These lasers and filters are widely employed in fiber-optic communication systems and typically operate in a wavelength range of 1.25 to 1.65 microns. A common feature of such devices is the presence of a regrown interface at the grating, across which electrical charge is injected. FIGS. 1A-C show a simplified schematic of how a typical tunable DBR laser is made. Referring to FIG. 1A, a waveguide layer 104 and a multi-quantum well layer 100 are grown on an n-type Indium Phosphide (InP) substrate 108. In FIG. 1B, the multi-quantum well layer 100 is partially etched away, and a grating 112 is etched into the waveguide layer 104. In FIG. 1C, a p-type upper InP cladding layer 116 is grown, creating a regrown interface 120. During processing, a p-type tuning contact 124, p-type active region contact 132, and n-type contact 128 are applied to the device. Tuning in this device is accomplished by applying a forward bias between the p-type tuning contact 124, and the n-contact 128. This results in injection of charge across the re-grown interface 120, into the waveguide layer 104, reducing the refractive index of this region and tuning the laser to shorter wavelengths. Although the regrown interface 120 is illustrated as a straight dashed line in FIG. 1C, we note that the actual physical interface follows the grating surface, and is therefore corrugated.

The corrugated regrown interface 120 typically contains defects. The injection of charge across the corrugated regrown interface 120 can lead to enhanced defect migration from this interface. This, in turn, can lead to changes in tuning efficiency of the device over time. The net result is unpredictability in the wavelength of operation as a function of applied tuning current.

From the foregoing, it is clear that what is required is a technique for fabricating grating-based semiconductor opto-electronic devices that minimizes injection of charge across defective interfaces.

### SUMMARY OF INVENTION

The present invention provides an opto-electronic semiconductor device with a grating incorporated at a wafer-bonded interface. A p layer and an n layer lie above the wafer bonded interface, and the current injection path does not cross the wafer bonded interface. By employing two top contacts, charge injection is not required across a defective wafer bonded interface. This technique can be used to fabricate, among other devices, DFB lasers, tunable DBR lasers, grating assisted co-directional coupler lasers and extended tuning range SGDBR lasers. In the preferred embodiment of this invention, no regrowth is required to complete the epitaxial structure. In an alternate embodiment, the wafer bonded grating is combined with a regrowth step to complete the epitaxial structure.

In the preferred embodiment of this invention, a final wafer is assembled in the following way. First, a grating is etched into a host substrate. Next a laser epitaxial region is grown on a first source substrate creating a first source wafer, and a passive tuning epitaxial region is grown on a second source substrate creating a second source wafer. Throughout this specification the term “wafer” refers to substrate plus epitaxy. First and second source wafer sections are then cleaved out of the first and second source wafers, respectively. The two source wafer sections are then wafer bonded to the host wafer, and along their edges to each other. After substrate removal, a passive tuning region lies adjacent an active region, and a grating disposed at a wafer bonded interface lies buried beneath the passive region.

A further understanding of the nature and advantages of the present invention may be realized by reference to the remaining portions of the specifications and drawings.

### BRIEF DESCRIPTION OF THE DRAWINGS

FIG. 1A is a schematic representation of a first growth step in a prior art technique for making DBR lasers.

FIG. 1B is a schematic representation of a grating etch step in a prior art technique for making DBR lasers.

FIG. 1C is a schematic representation of a prior art DBR laser fabricated using epitaxial regrowth.

FIG. 2A is a schematic representation of a grating etched in a host substrate as a step in DFB laser fabrication according to the present invention.

FIG. 2B is a schematic representation of a laser epitaxial structure grown as part of DFB laser fabrication according to the present invention.

FIG. 2C is a schematic epitaxial cross-section of a DFB laser according to the present invention.

FIG. 3 is a schematic representation of a preferred ridge-waveguide embodiment of a DFB laser according to present invention.

FIG. 4 is a schematic representation of an alternate semi-insulating buried heterostructure embodiment of a DFB laser according to the present invention.

FIG. 5 is a flow-chart representation of a process for making a preferred ridge-waveguide embodiment of DFB lasers according to the present invention.

FIG. 6 is a flow-chart representation of a process for making an alternate semi-insulating buried heterostructure embodiment of DFB lasers according to the present invention.

FIG. 7A is a schematic representation of a grating etched over a portion of a host wafer as a step in fabrication of DBR lasers according to the present invention.

FIG. 7B is a schematic representation of a laser epitaxial region source wafer section and a passive tuning region source wafer section.

FIG. 7C is a cross-sectional schematic representation of a tunable DBR laser according to the present invention.

FIG. 8 is a schematic view of the preferred ridge-waveguide tunable DBR laser according to the present invention.

FIG. 9 is a flow chart representation of a process for the preferred method of making a ridge-waveguide tunable DBR laser according to the present invention.

FIG. 10A is a schematic representation of a grating etched over a portion of a host wafer, as a step in fabricating an alternate embodiment of tunable DBR lasers according to the present invention.

FIG. 10B is a schematic representation of a laser epitaxial region grown on a carrier substrate as a step in an alternate embodiment of tunable DBR lasers according to the present invention.

FIG. 10C is a schematic cross-section of the epitaxial structure after a wafer bonding step in an alternate embodiment of a tunable DBR laser according to the present invention.

FIG. 10D is a schematic cross-section of the epitaxial structure after a quantum well removal step in an alternate embodiment of a tunable DBR laser according to the present invention.

FIG. 10E is a schematic cross-section of the epitaxial structure after a cladding regrowth step in an alternate embodiment of a tunable DBR laser according to the present invention.

FIG. 11 is a flow chart representation of an alternate process for fabricating a tunable DBR laser in accordance with the present invention.

### REFERENCE NUMERALS IN DRAWINGS

100 Quantum well region in prior art tunable DBR laser

104 Waveguide layer in prior art tunable DBR laser

108 Substrate in prior art tunable DBR laser

112 Etched grating in prior art tunable DBR laser

116 P-type regrown cladding in prior art tunable DBR laser.

120 Regrown interface in prior art tunable DBR laser.

124 P-type tuning contact in prior art tunable DBR

128 N-type tuning contact in prior art tunable DBR laser.

132 P-type active contact in prior art tunable DBR laser.

140 Host wafer in DFB laser according to present invention.

144 Etched grating in DFB laser according to present invention.

148 Source substrate in DFB laser fabricated according to present invention

152 P-cladding in DFB laser according to present invention

156 Waveguide layer in DFB laser according to present invention.

158 Quantum wells in DFB laser according to present invention.

160 N-cladding in DFB laser according to present invention.

168 Optical mode profile in DFB laser according to present invention.

172 Wafer bonded interface in DFB laser according to present invention.

176 Etched region of grating in DFB laser according to present invention.

178 Unetched region of grating in DFB laser according to present invention.

179 Axis parallel to direction of light propagation in DFB laser according to present invention.

180 p-contact in DFB laser according to present invention.

181 Active p-contact in tunable DBR laser according to present invention.

182 Passive region p-contact in tunable DBR laser according to present invention.

184 N-contact in grating based lasers according to present invention.

188 Polyimide planarizing layers in grating based ridge-waveguide lasers according to present invention.

190 First ridge in ridge-waveguide grating based laser according to present invention.

194 Second ridge in ridge-waveguide grating based laser according to present invention.

200 Current path in grating-based semiconductor lasers according to present invention.

210 First ridge in alternate embodiment of DFB laser according to present invention.

220 Regrown semi-insulating layer in alternate embodiment of DFB laser according to present invention.

230 Second ridge in alternate embodiment of present invention.

240 First step in preferred process for fabricating DFB laser according to present invention.

242 Second step in preferred process for fabricating DFB laser according to present invention.

244 Third step in preferred process for fabricating DFB laser according to present invention.

246 Fourth step in preferred process for fabricating DFB laser according to present invention.

248 Fifth step in preferred process for fabricating DFB laser according to present invention.

250 Sixth step in preferred process for fabricating DFB laser according to present invention.

252 Seventh step in preferred process for fabricating DFB laser according to present invention.

260 First step in alternate process for fabricating DFB laser according to present invention.

262 Second step in alternate process for fabricating DFB laser according to present invention.

264 Third step in alternate process for fabricating DFB laser according to present invention.

266 Fourth step in alternate process for fabricating DFB laser according to present invention.

268 Fifth step in alternate process for fabricating DFB laser according to present invention.

270 Sixth step in alternate process for fabricating DFB laser according to present invention.

272 Seventh step in alternate process for fabricating DFB laser according to present invention.

280 Host substrate in preferred tunable DBR laser fabricated according to present invention.

284 Grating in preferred tunable DBR laser according to present invention.

288 Waveguide layer in active portion of preferred tunable DBR laser according to present invention.

290 Quantum wells in preferred tunable DBR laser according to present invention.

292 Active region source substrate in preferred tunable DBR laser according to present invention.

296 Passive region source substrate in preferred tunable DBR laser according to present invention.

300 Passive waveguide in preferred tunable DBR laser according to present invention.

304 Active region n-cladding in preferred tunable DBR laser according to present invention.

308 Active region p-cladding in preferred tunable DBR laser according to present invention.

312 Passive region n-cladding in preferred tunable DBR laser according to present invention.

316 Passive region p-cladding in preferred tunable DBR laser according to present invention.

320 Active region source wafer section in preferred tunable DBR laser according to present invention.

324 Passive region source wafer section in preferred tunable DBR laser according to present invention.

328 Horizontal wafer bonded interface in preferred tunable DBR laser according to present invention.

332 Vertical wafer bonded interface in preferred tunable DBR laser according to present invention.

336 Optical field profile in preferred tunable DBR laser according to present invention.

340 Active epitaxial region in preferred tunable DBR laser according to present invention.

344 Passive epitaxial region in preferred tunable DBR laser according to present invention.

350 First step in method for making preferred tunable DBR laser according to present invention.

354 Second step in method for making preferred tunable DBR laser according to present invention.

362 Third step in method for making preferred tunable DBR laser according to present invention.

366 Fourth step in method for making preferred tunable DBR laser according to present invention.

370 Fifth step in method for making preferred tunable DBR laser according to present invention.

374 Sixth step in method for making preferred tunable DBR laser according to present invention.

378 Seventh step in method for making preferred tunable DBR laser according to present invention.

400 Host Substrate in alternate embodiment of tunable DBR laser according to present invention.

404 Etched grating in alternate embodiment of tunable DBR laser according to present invention.

410 Source substrate in fabrication of alternate embodiment of tunable DBR laser according to present invention.

414 N-cladding in alternate embodiment of tunable DBR laser according to present invention.

418 P-cladding in alternate embodiment of tunable DBR laser according to present invention.

424 Waveguide layer in alternate embodiment of tunable DBR laser according to present invention.

426 Quantum wells in alternate embodiment of tunable DBR laser according to present invention.

428 Epitaxy in alternate embodiment of tunable DBR laser according to present invention.

430 Regrown p-cladding in alternate embodiment of tunable DBR laser according to present invention.

434 Vertical regrown interface in alternate embodiment of tunable DBR laser according to present invention.

438 Horizontal regrown interface in alternate embodiment of tunable DBR laser according to present invention.

450 First step in method for fabricating alternate embodiment of tunable DBR laser according to present invention.

454 Second step in method for fabricating alternate embodiment of tunable DBR laser according to present invention.

458 Third step in method for fabricating alternate embodiment of tunable DBR laser according to present invention.

462 Fourth step in method for fabricating alternate embodiment of tunable DBR laser according to present invention.

466 Fifth step in method for fabricating alternate embodiment of tunable DBR laser according to present invention.

470 Sixth step in method for fabricating alternate embodiment of tunable DBR laser according to present invention.

474 Seventh step in method for fabricating alternate embodiment of tunable DBR laser according to present invention.

478 Eighth step in method for fabricating alternate embodiment of tunable DBR laser according to present invention.

482 Ninth step in method for fabricating alternate embodiment of tunable DBR laser according to present invention.

### DETAILED DESCRIPTION OF PREFERRED AND ALTERNATE EMBODIMENTS

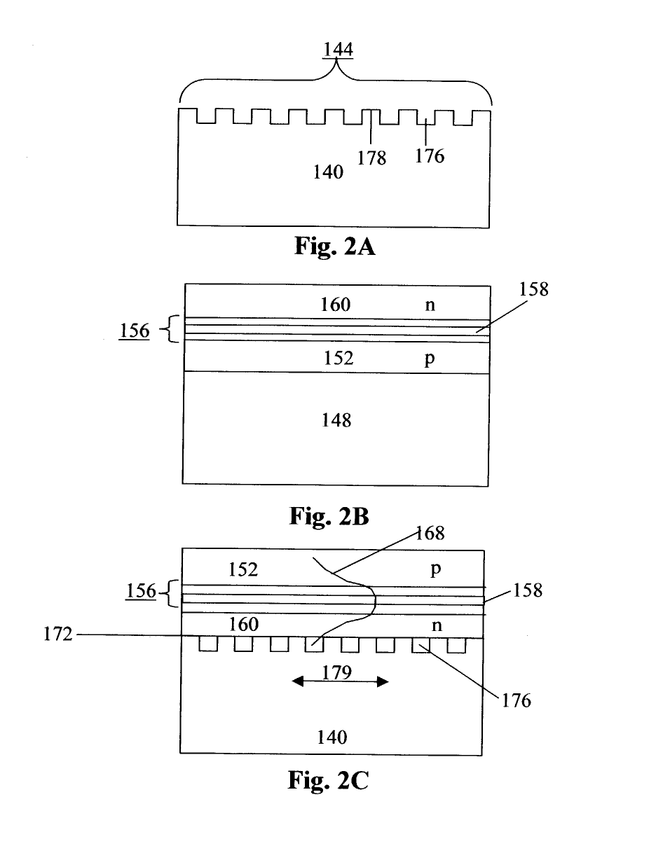

FIGS. 2A-C, 3 illustrate how a grating is incorporated at a wafer bonded interface in a DFB laser in accordance with the present invention. The discussion which follows could also apply to a grating based filter instead of a laser. Throughout this specification, the term “wafer bonding,” is assumed to refer to the joining of two semiconductor surfaces through the application of heat and/or pressure, and with or without the use of interfacial adhesive layers. The two semiconductors may or may not differ in composition or lattice constant. Similarly, the term “wafer bonded interface,” is assumed to comprise interfacial material if such material is employed, and the chemical bonds at that interface regardless of their nature. Additionally, “wafer bonded interfaces” or “bonded surfaces” implicitly exclude interfaces between grown epitaxial layers, between grown layers and substrates, or the surfaces between atomic planes in a continuous crystal.

In FIG. 2A, a grating 144 comprising recessed regions 176 and unetched regions 178 is patterned on the surface of a host wafer 140, which is preferably made of Indium Phosphide (InP). This etch is preferably accomplished using a Chlorine-based reactive ion etch, to a depth of approximately 1000 Angstroms, with photoresist as a masking layer during etching. In FIG. 2B, the epitaxy for the DFB laser is grown in inverted form on a source substrate 148. This epitaxy consists of a p-InP cladding layer 152, an undoped Indium Gallium Arsenide Phosphide (InGaAsP) waveguide layer 156 which comprises quantum wells 158, and an n-InP cladding layer 160. FIG. 2C illustrates the final epitaxial structure which remains after the surface of n-cladding layer 160 has been bonded to the host wafer 140 at the corrugated grating surface 144, and the substrate 148 has been removed. The net result is a p-up laser epitaxial structure, with the grating 144 at a wafer bonded interface 172. The recessed regions 176 form air pockets surrounded by semiconductor. The air pockets 176 could be filled with other low index material such as silicon dioxide in an alternate, but not preferred, embodiment. After further processing of this device, light will propagate in a direction parallel to an axis 179.

In FIG. 2C, the thickness of the n-cladding 160 must be controlled to achieve the desired overlap of an optical field profile 168 with the grating 144, and therefore the desired grating coupling constant. Throughout this specification, whenever we refer to “optical field profile,” we mean an eigenmode or allowed modal solution of the layer structure. This thickness of the n-cladding can be calculated by means well-known to those skilled in the art of grating based lasers and waveguide devices, to achieve whatever coupling constant is desired. Typical thickness of the cladding 160 will be on the order of 1 micron.

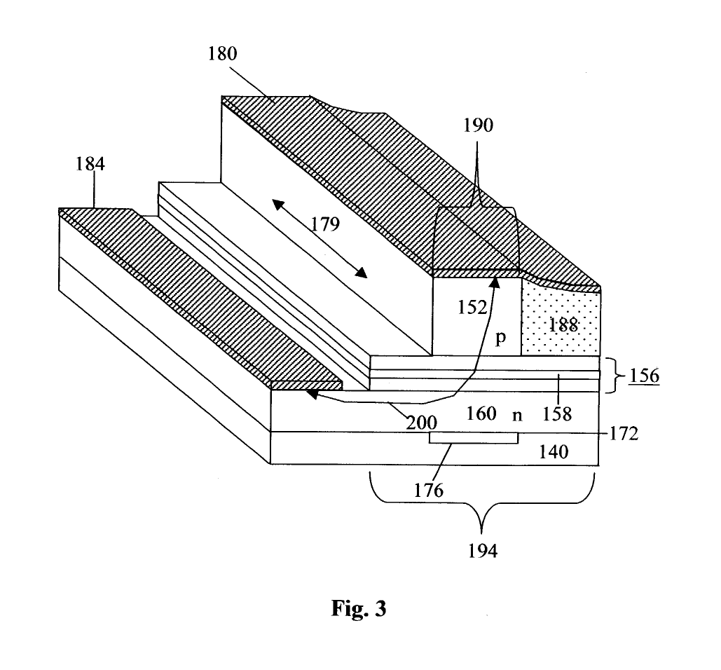

In the preferred embodiment, the DFB laser is processed into a ridge-waveguide structure with two top contacts, as illustrated in FIG. 3. The p-cladding 152 has been etched into a first ridge 190 down to the waveguide layer 156, which confines the holes injected from a p-contact 180 to the width of the ridge 190. An n-contact 184 is placed in the n-cladding 160, after etching a second ridge 194 through the waveguide layers 156. The second ridge 194 is wider than the first ridge 190 by at least several microns, to prevent charge carriers injected into the quantum wells 158 over the width of ridge 190, from diffusing to the exposed surface at the edge of ridge 194, where they may recombine and reduce device efficiency. A polyimide planarizing layer 188 supports a portion of the p-contact 180.

FIG. 3 shows a portion of one grating recessed region 176. The other recesses in the grating are not visible because they lie buried under the ridge 190 along the axis of light propagation 179. The width of recess 176 is roughly equal to the width of the ridge 190. Etching this recess wider is unnecessary, because the majority of the optical field is confined to the width of ridge 190, and etching a wider recess only results in compromising device thermal conductivity, as heat cannot escape efficiently through airgap regions.

During device operation a forward bias is applied between the p-contact 180 and the n-contact 184, resulting in injection of electrons and holes into the quantum wells 158, and flow of current along a path 200 between the terminals 184 and 180 without crossing the defective wafer bonded interface 172. Because no current is flowing across defective interfaces, the reliability of this device should be superior to prior art devices incorporating current injection across regrown interfaces. We refer to the interface 172 as an electrically passive interface, because no electrical charge is flowing across it. Throughout this specification, the term “electrically passive interface” is one across which substantially no charge flows during device operation.

We note that the structure of FIG. 3 could be processed with a backside n-contact to the host substrate 140. This would necessitate current injection through the wafer bonded interface 172, and is therefore not the preferred embodiment. The structure would still retain the advantage, however, of having been assembled without out the need for epitaxial regrowth.

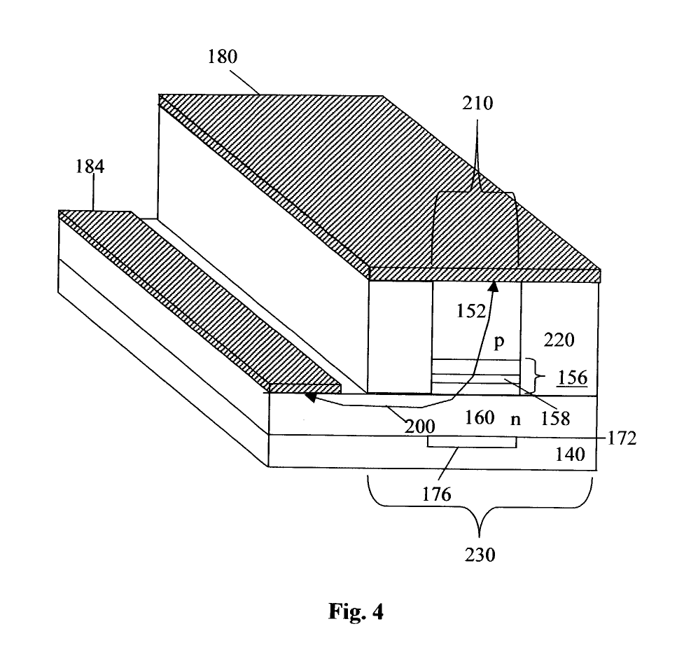

FIG. 3 illustrates the preferred ridge-waveguide geometry into which these devices are processed. FIG. 4 illustrates an alternate geometry, in which semi-insulating material 220 is regrown around a ridge 210, which extends through the waveguide layers 156. The semi-insulating material 220 serves to confine the carriers injected over the width of ridge 210, and to also provide mechanical support for the p-contact 180, in place of the polyimide layer 188 of FIG. 3. A second ridge 230 is etched before deposition of n-metal 184, analogous the ridge 194 of FIG. 3. Again, current is injected along the path 200 between contacts 180 and 184, avoiding the wafer bonded interface 172.

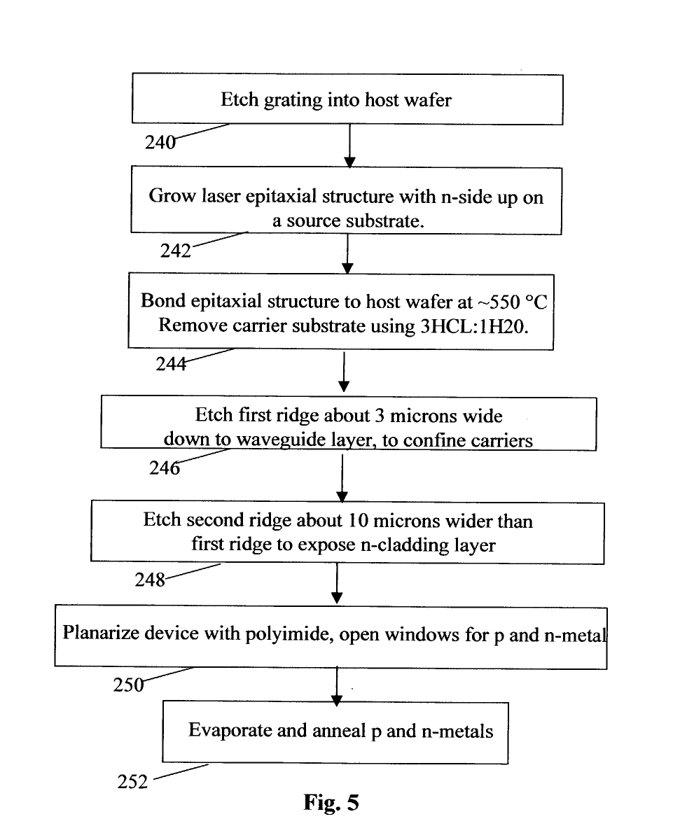

FIG. 5 is a flow chart illustrating the process used to fabricate the preferred device structure of FIG. 3. Referring to FIG. 5, in a first step 240, a grating is etched into a host wafer, preferably using a Chlorine-based reactive ion etching in an InP host wafer. In a second step 242, a laser epitaxial structure is grown n-side up, preferably on an InP source substrate. A stop-etch layer is grown underneath the epitaxial structure to facilitate substrate removal. In a third step 244, the n-surface of the epitaxial region is wafer bonded to the corrugated host wafer surface. This wafer bond can be accomplished with a commercial wafer bonder manufactured by Karl Suss or by Scientific Sealing Technologies (SST). If the materials are all grown on InP substrates, as is the case in the preferred embodiments, one can use a temperature of approximately 550° C., and a pressure in the range of 100-400 pounds per square inch, both of which can be determined by straightforward empirical means. The InP carrier substrate is removed using a solution of approximately 3HCL to 1H2O. Other etches for other substrates are well known to those skilled in the art, and pressures and temperatures for bonding other materials are either known to those skilled in the art, or capable of being determined by straightforward empirical means. In a step 246, a first ridge of about 3 microns is preferably wet-etched at down to the waveguide layer or stopping approximately 300 Angstroms above the waveguide layer. In a step 248, a second ridge about 10 microns wider than the first ridge is preferably wet-etched down to the n-contact layer. The device is then planarized in a step 250, and windows are opened for p and n metal. In a final step, 252, p and n metals are deposited by electron beam evaporation and annealed.

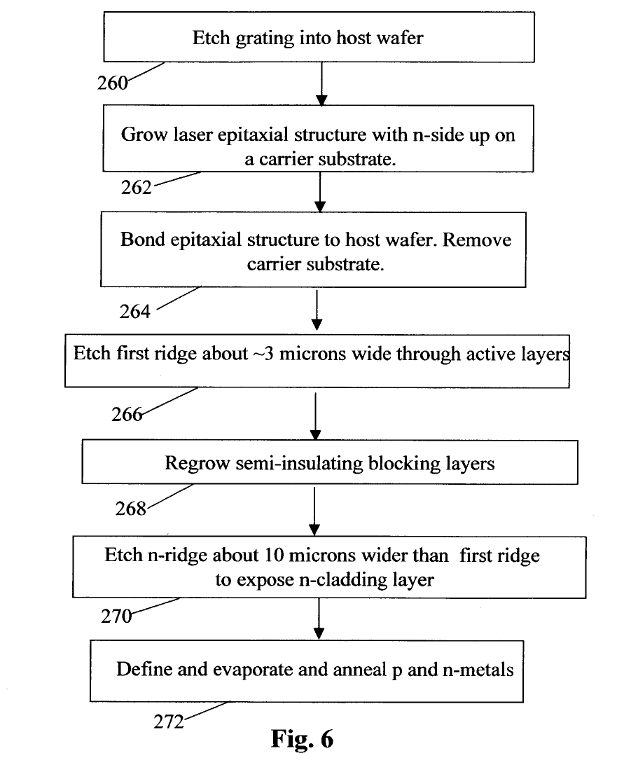

FIG. 6 is a flow chart illustrating the process used to fabricate the alternate device structure of FIG. 4. In steps 260-266, the fabrication sequence is essentially identical to steps 240-246 of FIG. 5. In a step 268 of FIG. 6, semi-insulating blocking layers are regrown around the first ridge. In a step 270, a second ridge 10 microns wider than the first ridge is etched. In step 272, p and n-metals are defined, evaporated, and annealed.

FIGS. 2-6 describe how a DFB laser can be fabricated according to the present invention. The present invention can also be applied to fabricate DBR lasers, sampled grating DBR lasers, and lasers employing co-directional couplers. A common feature of these latter types of lasers is variation in the epitaxial structure from active to passive within the plane of the wafer within the device. The description which follows will assume a simple tunable DBR structure, but this is illustrative and not limiting. The same structure could be used to realize a sampled grating DBR laser, co-directional coupler laser or other grating-based lasers incorporating active/passive transitions.

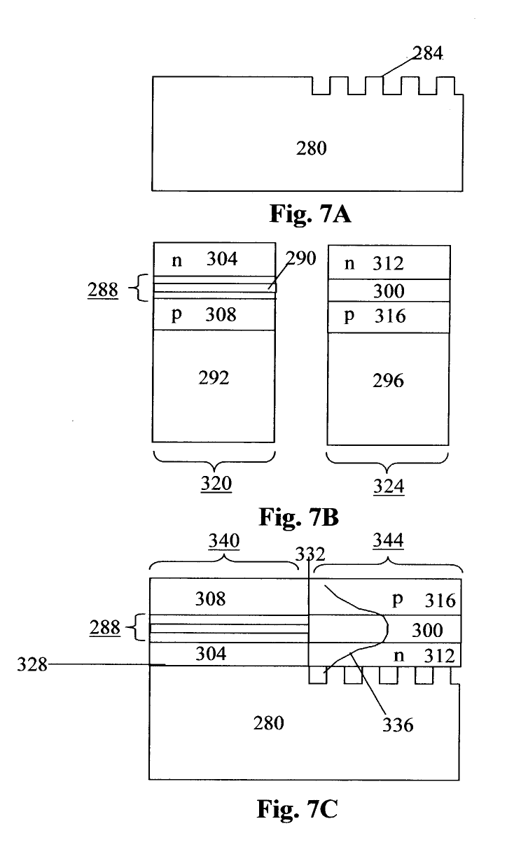

FIGS. 7A-C illustrate how the epitaxy for a tunable DBR laser is preferably assembled. First, a grating 284 is etched over a portion of a host wafer 280, as shown in FIG. 7A. FIG. 7A illustrates only a portion of a wafer. A full wafer would have grating sections repeatedly alternating with non-grating sections, to enable wafer scale fabrication of multiple devices simultaneously. Next, two types of source wafer sections 320 and 324 are cleaved from separate growth runs, as shown in FIG. 7B. The source wafer section 320 contains laser epitaxy, containing the quantum wells 290 within waveguide layer 288, p-cladding 308 and n-cladding 304 on a substrate 292. Source wafer section 324 contains a passive waveguide layer 300, p-cladding 316, and n-cladding 312 on a substrate 296. FIG. 7C shows the assembled epitaxial structure after vertical and lateral wafer bonding according to the technique described in co-pending U.S. patent application entitled “Multiple Epitaxial Region Wafers with Optical Connectivity,” by Vijaysekhar Jayaraman, filed Jan. 15, 2003. The net result is a tunable DBR laser with an active region 340 adjacent a passive region 344, separated by a vertical wafer-bonded interface 332, both sitting on host substrate 280 and joined at a horizontal wafer bonded interface 328. FIG. 7C shows only two epitaxial regions on the host substrate 280, but in reality the completed wafer is populated with a large number of laser epitaxial regions 340 alternating with passive waveguide epitaxial regions 344.

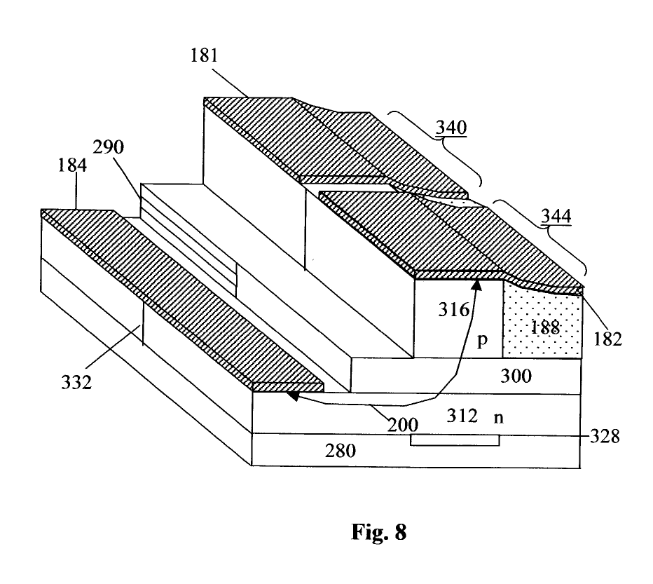

Subsequent to assembly of the appropriate epitaxial structure illustrated in FIG. 7C, the processed device structure is analogous to FIG. 3 in the preferred ridge waveguide geometry, and analogous to FIG. 4 in an alternate semi-insulating buried heterostructure geometry. FIG. 8 illustrates the ridge waveguide device geometry for the tunable DBR laser. Like FIG. 3, the ridge waveguide tunable DBR laser of FIG. 8 has top n-contact 184, and polyimide planarizing layer 188. The single p-contact 180 of FIG. 3 is replaced in FIG. 8 by a split p-contact, with an active p-contact 181 injecting current into the active portion 340, and a passive p-contact 182 injecting current into the passive portion 344. The current flow follows the path 200 between the p-contact 182 or 181 and the n-contact 184, and avoids crossing the defective wafer bonded interfaces 328 and 332. An alternate semi-insulating buried heterostructure geometry is analogous to FIG. 4, and is not shown for the tunable DBR laser.

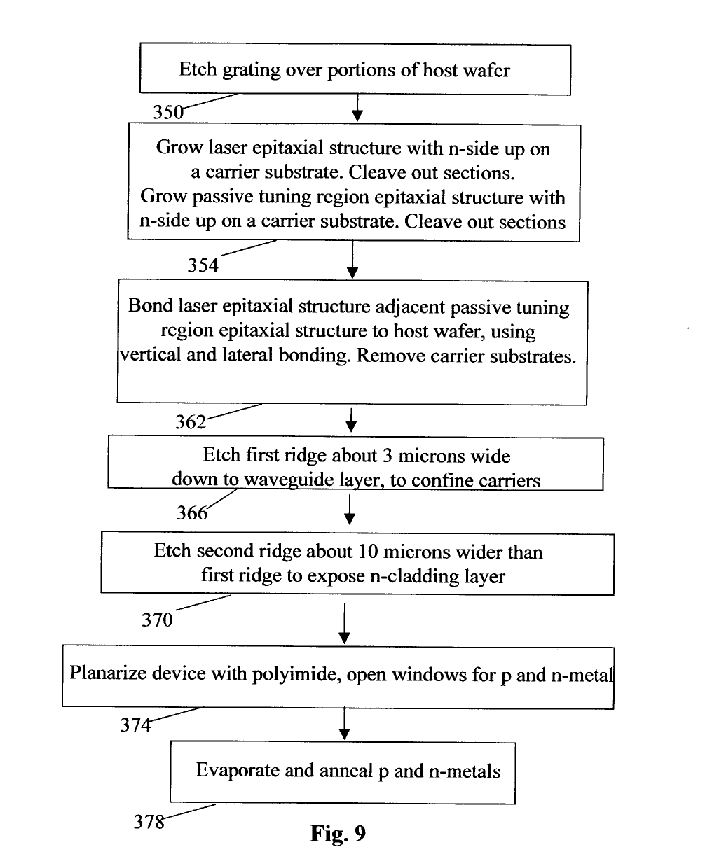

FIG. 9 summarizes the process flow for fabricating the preferred ridge waveguide tunable DBR laser of FIG. 8 in accordance with the present invention. In a first step 350, grating is etched over portions of a host wafer. In a step 354, a laser epitaxial region and a passive waveguide epitaxial region are grown on separate source substrates. Sections of each are cleaved out. In a step 362, both the laser epitaxial structure and the waveguide epitaxial structure are bonded to the host wafer using the vertical and lateral bonding technique of co-pending US patent application “Multiple Epitaxial Region Wafers with Optical Connectivity,” by Vijaysekhar Jayaraman, filed Jan. 15, 2003. Both source substrates are removed. This is accomplished with 3HCL:1H2O if the substrates are InP, stopping on an InGaAs stop etch layer. In a step 366, a first ridge of about 3 microns width is etched down to approximately the waveguide layer, to confine carrier injection. In a step 370, another ridge is etched, about 10 microns wider than the first, down to the n-cladding layer, to enable contact to this layer. In a step 374, the device is planarized with polyimide, and windows are opened for p and n metal. In a final step 378, p and n metals are evaporated.

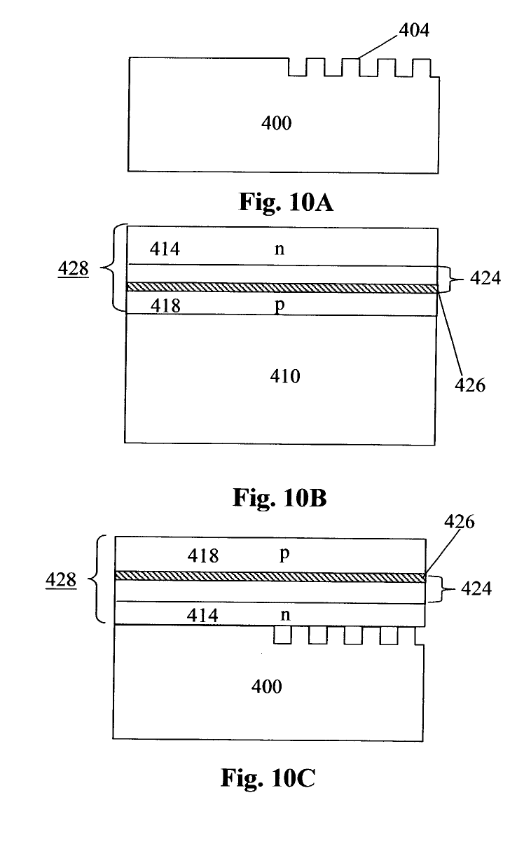

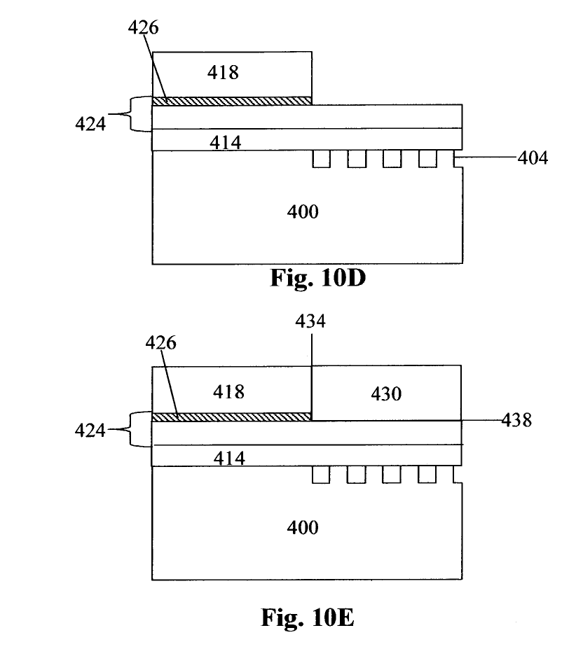

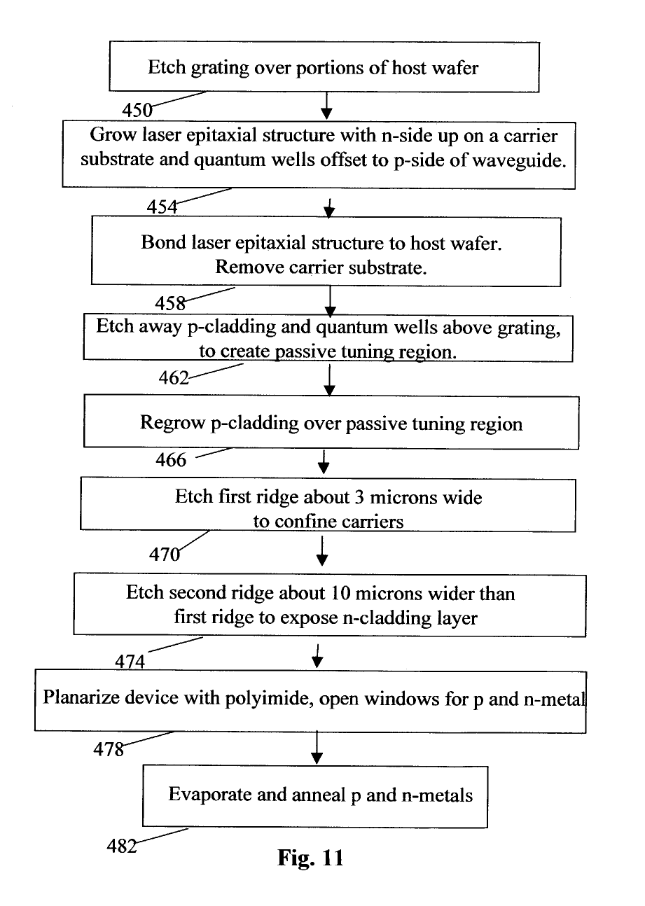

FIGS. 7-9 illustrate the preferred embodiment for a tunable DBR laser according to the present invention. In an alternate but not preferred embodiment, it is possible to circumvent the vertical wafer bonded interface of FIG. 7C. This alternate embodiment is illustrated in FIGS. 10A-E, and in the flow chart of FIG. 11.

Referring to FIG. 10A and FIG. 11, in a first step 450, a grating 404 is etched into portions of a host wafer 400. In FIG. 10B, and a step 454 of FIG. 11, a laser epitaxial structure 428 comprising a p-cladding 418, quantum wells 426 offset to the p-side of a waveguide layer 424, and an n-cladding 414 are grown with n-side up on a source substrate 410. In FIG. 10C and a step 458 of FIG. 11, the laser epitaxial structure 428 is bonded to the host wafer 400, and the source substrate 410 is removed. In FIG. 10D and a step 462 of FIG. 11, the p-cladding 418 and quantum wells 426 are removed from the bonded wafer over the etched grating 404, in preparation for creating a passive tuning region of the device. In a step 466, and FIG. 10E, a second p-cladding 430 is regrown over the device, creating a nominally vertical regrown interface 434 and a horizontal regrown interface 438. This completes the epitaxial structure.

After assembly of the epitaxial structure as in FIGS. 10A-E, the device processing proceeds identically to that described in FIG. 9 for the device of FIG. 8. Referring to FIG. 11, in a step 470, a first ridge of about 3 micron width is etched to confine carriers. This ridge etch stops on the waveguide layer 424, which has been partially etched to remove the quantum wells 426 in the passive region, but still comprises the quantum wells 426 in the active region. In a step 474, a second ridge approximately 10 microns wider than the first ridge is etched through the waveguide to the n-cladding. In a step 478, the device is planarized with polyimide, and windows are opened for p-metal and n-metal. In a final step 482, p and n metal are evaporated, and contacts are annealed.

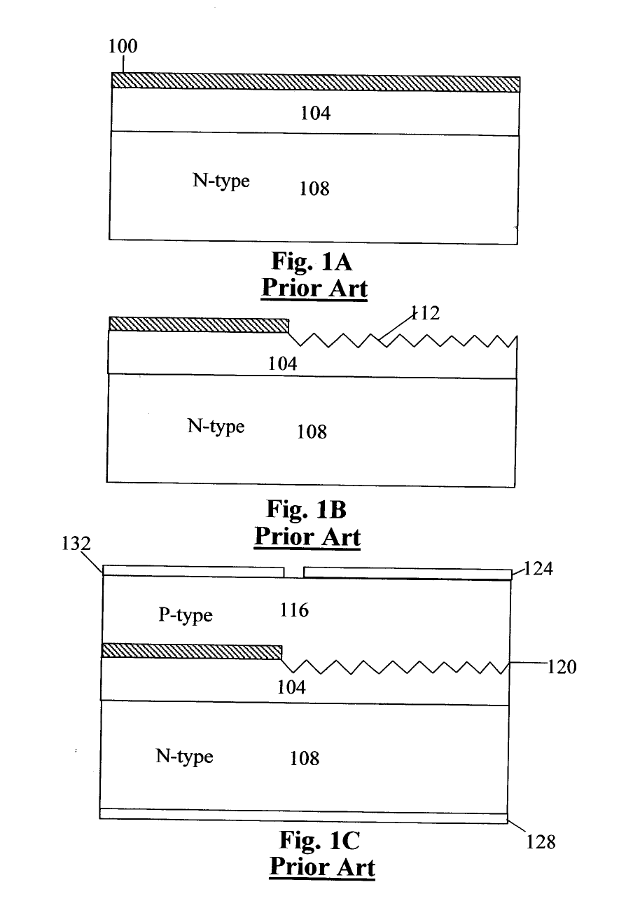

The alternate non-preferred embodiment of FIGS. 10A-E avoids the lateral wafer bond leading to the vertical wafer bonded interface 332 in FIG. 7C. However, devices processed from the structure of FIG. 10E require current injection across the defective regrown interface 438. This planar regrown interface likely has fewer defects than the corrugated re-grown interface 120 of FIG. 1C in the prior art, and thus tuning currents in the passive tuning region are likely to be more stable. Thus, the alternate embodiment of FIGS. 10A-E and FIG. 11 has advantages over prior art approaches requiring current injection across regrown interfaces incorporating a grating.

All of the preceding figures illustrating wafer bonded interfaces show direct semiconductor to semiconductor bonds. This is the preferred embodiment, but it is also possible to introduce interfacial adhesive layers such as epoxy at the wafer bonded interface. Additionally, although the preferred embodiments shown in these figure show the p-region at the top of the device, the p and n-regions could be reversed in alternate embodiments. We refer to the doping polarity of a region as its conductivity type. Thus a p region could be a first conductivity type, and an n-region could be a second conductivity type, and p and n regions are always of opposite conductivity type.

While this invention has been particularly shown and described with references to preferred and alternate embodiments thereof, it will be understood by those skilled in the art that various changes in form and details may be made therein without departing from the spirit and scope of the invention as defined by the appended claims.

What is claimed is:

1. An opto-electronic semiconductor device comprising,
A waveguide layer disposed between a p-layer and an n-layer
a grating disposed at an electrically passive wafer-bonded interface
an optical field profile which substantially overlaps said grating and said waveguide layer and
means for injecting holes from said p-layer and electrons from said n-layer into said waveguide layer

2. The opto-electronic semiconductor device of claim 1, wherein said waveguide layer further comprises laser active material:

3. The opto-electronic semiconductor device of claim 2, wherein said active material is a multi-quantum well region.

4. The opto-electronic semiconductor device of claim 1, where said waveguide layer is passive.

5. The opto-electronic semiconductor device of claim 4, further comprising an active portion adjacent said passive waveguide layer.

6. The opto-electronic semiconductor device of claim 5, further comprising a vertical wafer bonded interface between said passive waveguide layer and said active portion.

7. The opto-electronic semiconductor device of claim 5, further comprising a regrown cladding above said passive waveguide region, and a planar regrown interface between said cladding and said passive waveguide.

8. The opto-electronic semiconductor device of claim 5, further comprising a first electrical contact for injecting carriers into said passive region and a second electrical contact for injecting carriers into said active portion.

9. The opto-electronic semiconductor device of claim 1, wherein said opto-electronic semiconductor device is a distributed feedback laser.

10. The opto-electronic semiconductor device of claim 1, wherein said opto-electronic semiconductor device is a distributed Bragg Reflector laser.

11. The opto-electronic semiconductor device of claim 1, wherein said opto-electronic semiconductor device is a sampled grating Distributed Bragg Reflector laser.

12. The opto-electronic semiconductor device of claim 1, further comprising a grating-assisted co-directional coupler.

13. The opto-electronic semiconductor device of claim 1, wherein said opto-electronic semiconductor device is a tunable laser.

14. The opto-electronic semiconductor device of claim 1, further comprising a ridge-waveguide geometry.

15. The opto-electronic semiconductor device of claim 1, further comprising a semi-insulating buried heterostructure geometry.

16. A method for fabricating grating-based semiconductor opto-electronic devices, the method comprising,
Etching a grating into a host substrate
Growing a first epitaxial region on a first source substrate to create a first source wafer with a first planar surface, said first epitaxial region comprising a first conducting layer of a first conductivity type and a second conducting layer of a second conductivity type opposite said first conductivity type,
Bonding said first epitaxial region to said host substrate,
Removing said first source substrate, and
Depositing a first contact metal on said first conducting layer and a second contact metal on said second conducting layer.

17. The method of claim 16, further comprising,
Growing a second epitaxial region on a second source substrate creating a second source wafer with a second planar surface,
Cleaving a section of said first source wafer creating a first source wafer section with a first edge substantially perpendicular to said first planar surface,
Cleaving a section of said second source wafer creating a second source wafer section with a second edge substantially perpendicular to said second planar surface,
Bonding said second epitaxial region to said host wafer and said second edge to said first edge.

18. The method of claim 17, wherein said first epitaxial region is an active region and said second epitaxial region is a passive region.

19. The method of claim 16, further comprising,
Etching a first ridge to define a region of current injection, and
Etching a second ridge to access said second conducting layer.

20. The method of claim 19, further comprising regrowing a semi-insulating region around said first ridge.
